(19) United States
(12) Patent Application Publication
(10) Pub. No.: US 2025/0029961 A1
(43) Pub. Date: Jan. 23, 2025

(54) LIGHT-EMITTING CHIP, LIGHT BOARD, AND METHOD OF ASSEMBLING LIGHT-EMITTING CHIP

(71) Applicant: HKC CORPORATION LIMITED, Shenzhen (CN)

(72) Inventors: Hongsong Wang, Shenzhen (CN); Junfeng Xie, Shenzhen (CN)

(21) Appl. No.: 18/733,843

(22) Filed: Jun. 5, 2024

(30) Foreign Application Priority Data
Jul. 17, 2023 (CN) 202310872965.9

(51) Int. Cl. H01L 25/075; H01L 33/62

(52) U.S. Cl. CPC H01L 25/0753; H01L 33/62; H01L 2933/0066

(57) ABSTRACT

A light-emitting chip, a light board, and a method of assembling the light-emitting chip are disclosed. The light-emitting chip includes a first chip, a second chip, and a third chip. The second chip includes a first side and a second side. The first side includes a first protrusion. The second side includes a second protrusion. The first chip includes a first groove. The third chip includes a second groove. The first chip is disposed on the first side, and the first groove is mated with the first protrusion. The third chip is disposed on the second side, and the second groove is mated with the second protrusion. The first chip and the third chip are symmetrically arranged about a central axis of the second chip so as to be combined to form the light-emitting chip.

### CROSS-REFERENCE TO RELATED APPLICATIONS

This application claims the priority and benefit of Chinese patent application number 2023108729659, titled “Light-emitting Chip, Light board, and Method of Assembling Light-emitting Chip” and filed Jul. 17, 2023 with China National Intellectual Property Administration, the entire contents of which are incorporated herein by reference.

### TECHNICAL FIELD

This application relates to the field of light-emitting diodes, and more particularly relates to a light-emitting chip, a light board, and a method of assembling the light-emitting chip.

### BACKGROUND

The description provided in this section is intended for the mere purpose of providing background information related to the present application but doesn't necessarily constitute prior art.

With the innovation and development of LED (light-emitting diode) technology, Micro-LED (Micro Light Emitting Diode Display) display technology has become a new generation of display technology. It consists in miniaturizing and matrixing the LED structures, so that the size of a single LED chip is reduced to tens of microns or even a few microns, and each LED pixel is addressed and individually driven to emit light. Since Micro-LED chip displays have the advantages of high resolution, high brightness, long life span, wide operating temperature range, strong anti-interference ability, fast response speed, and low power consumption, Micro-LED has important application values in the fields of high-resolution display, helmet display, augmented reality, high-speed visible light communication, micro-projector, optogenetics, and wearable electronics.

A full-color gamut LED display is assembled from Micro-LED chips in three primary colors of red, green, and blue (RGB) on a substrate in a certain arrangement. In a possible RGB arrangement, each group uses three chips of red, green, and blue, which are evenly and horizontally spaced to realize an RGB effect. The size of a single group is relatively large, and it is also difficult to assemble in that three chips of red, green, and blue need to be arranged in sequence. The number of chips transferred in a mass transfer process is relatively large, which leads to relatively high requirements on the mass transfer process of the Micro-LEDs and a relatively low mass production yield.

### SUMMARY

In view of the above, it is one purpose of this application to provide a light-emitting chip, a light board, and a method of assembling the light-emitting chip. By setting the structure of the light-emitting chip, the requirements for the mass transfer process are reduced, and the production yield of Micro-LED displays using the light-emitting chip is improved.

This application discloses a light-emitting chip, which is used in light boards. The light-emitting chip includes a first chip, a second chip, and a third chip. The second chip includes a first side and a second side. The first side includes a first protrusion. The second side includes a second protrusion. The first chip includes a first groove. The third chip includes a second groove. The first chip is disposed on the first side, and the first groove mate with the first protrusion. The third chip is disposed on the second side, and the second groove only mates with the second protrusion. The first chip and the third chip are symmetrically arranged about a central axis of the second chip thus forming the light-emitting chip in combination.

In some embodiments, a first magnetic attraction layer is disposed on the first protrusion, a second magnetic attraction layer is disposed in the first groove, a third magnetic attraction layer is disposed on the second protrusion, and a fourth magnetic attraction layer is disposed in the second groove. The first magnetic attraction layer and the second magnetic attraction layer attract each other. The third magnetic attraction layer and the fourth magnetic attraction layer attract each other. The first magnetic attraction layer and the third magnetic attraction layer have opposite polarities. The second magnetic attraction layer and the fourth magnetic attraction layer have opposite polarities.

In some embodiments, the light-emitting surface area of the first chip is S1, the light-emitting surface area of the second chip is S2, and the light-emitting surface area of the third chip is S3, where the S1, the S2 and the S3 are all equal.

In some embodiments, the light-emitting surface of the light-emitting chip includes a first electrostatic coating. A second electrostatic coating is disposed on the side of the light-emitting chip on which the first chip is disposed. A third electrostatic coating is disposed on the side of the light-emitting chip where the third chip is disposed. A front side of the light-emitting chip includes a fourth electrostatic coating. A back side of the light-emitting chip includes a fifth electrostatic coating. The second electrostatic coating and the third electrostatic coating have opposite charge polarities. The fourth electrostatic coating and the fifth electrostatic coating have opposite charge polarities.

In some embodiments, the first chip includes a first connecting piece. The third chip includes a second connecting piece. When the first chip and the third chip are combined with the second chip to form the light-emitting chip, the first chip and the second chip are electrically connected through the first connecting piece, and the third chip and the second chip are connected through the second connecting piece. The first connecting piece and the second connecting piece are conductor layers.

In some embodiments, the first electrostatic coating is a positively charged electrostatic coating.

In some embodiments, the conductor layer is made of metallic copper.

In some embodiments, the light-emitting chip has a rectangular structure.

This application further discloses a light board used in a display device, including a bottom plate and the light-emitting chip as described above. The light-emitting chip is installed on the bottom plate.

This application further discloses a method of assembling a light-emitting chip, which is applied to the light-emitting chip as described above, including the following operations:
placing the first chips, the second chips and the third chips into an assembling apparatus;
starting the assembling apparatus to move the first chips, the second chips, and the third chips to be combined and assembled together to form the light-emitting chip;
wherein the first groove only mate with the first protrusion, and the second groove only mate with the second protrusion;

In the light-emitting chip of this application, a first protrusion and a second protrusion are disposed on the second chip 120, a first groove is defined in the first chip 110, and a second groove is defined in the third chip 130, so that the first chip and the third chip may be respectively installed on the first side and the second side of the second chip that are opposite to each other, so that the first chip, the second chip, and the third chip are assembled together to form the light-emitting chip. Furthermore, the first protrusion only mate with the first groove, and the second protrusion only mate with the second groove. There will be no assembly errors of the light-emitting chip; there will only be situations where the assembly of the light-emitting chip is completed or not. When the light-emitting chip is installed in a Micro-LED display screen, compared with the RGB solution that requires three chips of red, green and blue to be evenly spaced together on a horizontal plane to form an RGB effect, the light-emitting chip of this embodiment has a relatively low requirement for the mass transfer processes when installed in a Micro-LED display. Since the first chip, the third chip, and the second chip are first assembled together to form the light-emitting chip which is then installed in the light board, the number of chips that require mass transfer and installation is sharply reduced for the light board using the light-emitting chip of this embodiment, and the requirements on the mass transfer process is reduced, thereby improving the production yield of Micro-LED displays, and also reducing the difficulty of assembly, making it easier to produce Micro-LED displays.

### BRIEF DESCRIPTION OF DRAWINGS

The accompanying drawings are used to provide a further understanding of the embodiments according to this application, and constitute a part of the specification. They are used to illustrate the embodiments according to this application, and explain the principle of this application in conjunction with the text description. Apparently, the drawings in the following description merely represent some embodiments of the present disclosure, and for those having ordinary skill in the art, other drawings may also be obtained based on these drawings without investing creative efforts. A brief description of the accompanying drawings is provided as follows.

FIG. 1 is a schematic diagram of a light-emitting chip according to the first embodiment of this application.

FIG. 2 is a schematic cross-sectional view of the light-emitting chip according to the first embodiment of this application.

FIG. 3 is an exploded cross-sectional view of the light-emitting chip according to the first embodiment of this application.

FIG. 4 is a schematic diagram of an assembling apparatus according to a second embodiment of this application.

FIG. 5 is a flow chart of a method of assembling a light-emitting chip according to a third embodiment of this application.

FIG. 6 is a schematic diagram of a light-emitting chip according to a fourth embodiment of this application.

FIG. 7 is a schematic diagram of a light board according to a fifth embodiment of this application.

FIG. 8 is an enlarged view of portion A shown in FIG. 7 of this application.

FIG. 9 is a schematic diagram of a light board according to a sixth embodiment of this application.

FIG. 10 is a schematic diagram of a display device according to a seventh embodiment of this application.

In the drawings: 100. Light-emitting chip; 110. First chip; 111. First groove; 112. Second magnetic attraction layer; 113. First connecting piece; 120. Second chip; 121. First side; 122. Second side; 123. First protrusion; 124. Second protrusion; 125. First magnetic attraction layer; 126. Third magnetic attraction layer; 130. Third chip; 131. Second groove; 132. Fourth magnetic attraction layer; 133. Second connecting piece; 140. First electrostatic coating; 141. Second electrostatic coating; 142. Third electrostatic coating; 143. Fourth electrostatic coating; 144. Fifth electrostatic coating; 200. Light board; 300. Bottom plate; 301. Accommodating groove; 302. Receiving groove; 310. Partition plate; 311. Sub-capacitor plate; 320. Sunken groove; 321. Elastic piece; 322. Support plate; 400. Main capacitor plate; 500. Assembling structure; 510. Driving piece; 520. Transmission assembly; 521. First transmission gear; 522. Second transmission gear; 523. Crank rod; 530. Connecting rod; 531. Suction piece; 600. Power supply board; 610. Connecting hole; 700. Driving circuit; 800. Display device; 900. Assembling apparatus; 910. First turntable; 911. First screening hole; 912. First snap piece; 920. Second turntable; 921. Second Screening hole; 922. First catching groove; 930. Third turntable; 931. Third screening hole; 940. First driving assembly; 950. Second driving assembly.

### DETAILED DESCRIPTION OF EMBODIMENTS

It should be understood that the terms used herein, the specific structures and function details disclosed herein are intended for the mere purposes of describing specific embodiments and are representative. However, this application may be implemented in many alternative forms and should not be construed as being limited to the embodiments set forth herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. Term “comprising”, “including”, and any variants thereof mean non-exclusive inclusion, so that one or more other features, integers, steps, operations, units, components, and/or combinations thereof may be present or added.

In addition, terms “center”, “transverse”, “up”, “down”, “left”, “right”, “vertical”, “horizontal”, “top”, “bottom”, “inside”, “outside”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure.

Furthermore, as used herein, terms “installed on”, “mounted on”, “connected to”, “coupled to”, “connected with”, and “coupled with” should be understood in a broad sense unless otherwise specified and defined. For example, they may indicate a fixed connection, a detachable connection, or an integral connection. They may denote a mechanical connection, or an electrical connection. They may denote a direct connection, a connection through an intermediate, or an internal connection between two elements. For those of ordinary skill in the art, the specific meanings of the above terms as used in this application can be understood depending on specific contexts.

This application will be described in detail below with reference to the accompanying drawings and optional embodiments. It should be noted that, should no conflict is present, the various embodiments or technical features described below can be combined arbitrarily to form new embodiments.

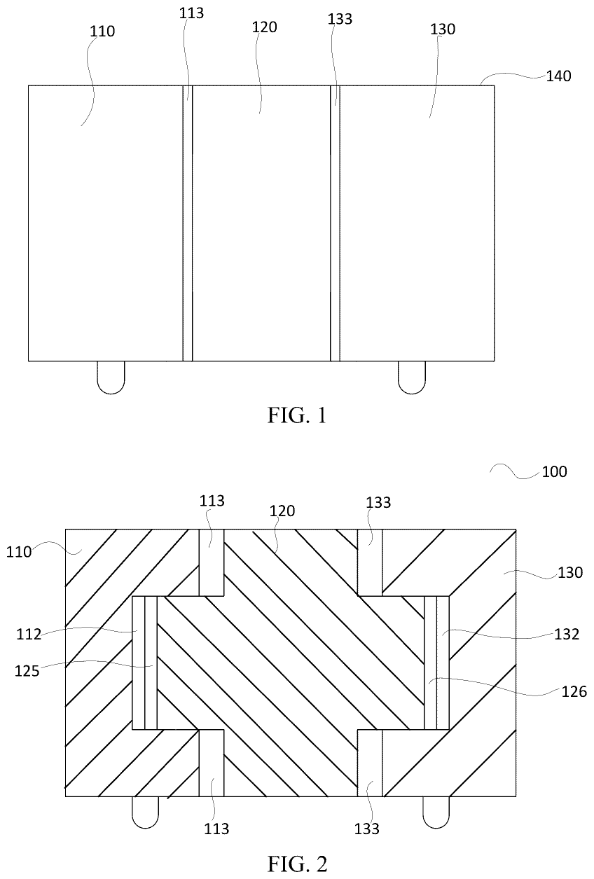

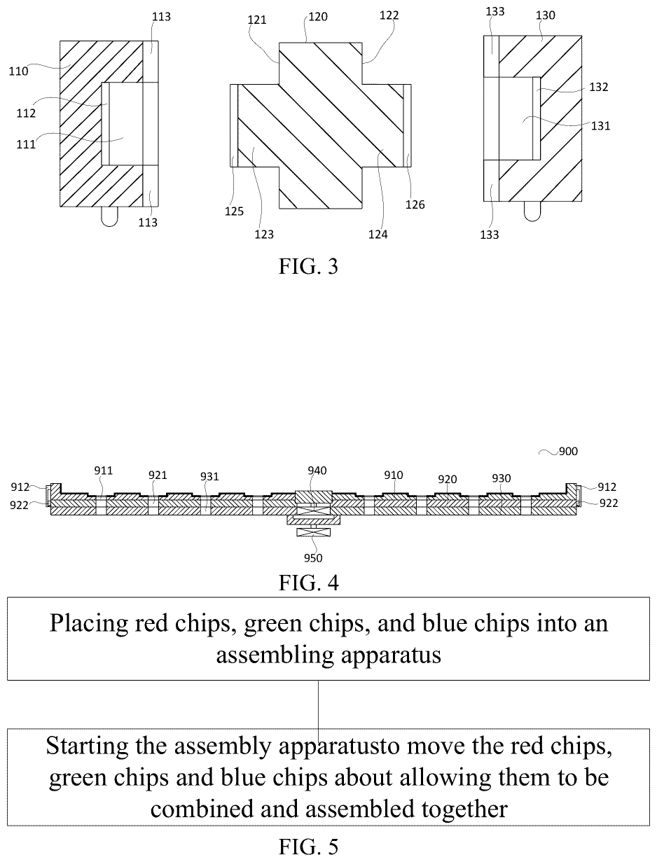

As illustrated in FIGS. 1 to 3, as a first embodiment of this application, a light-emitting chip 100 is disclosed. The light-emitting chip 100 is applied to a light board 200. The light-emitting chip 100 includes a first chip 110, a second chip 120, and a third chip 130. The second chip 120 includes a first side 121 and a second side 122. The first side 121 includes a first protrusion 123. The second side 122 includes a second protrusion 124. The first chip 110 includes a first groove 111. The third chip 130 includes a second groove 131. The first chip 110 is disposed on the first side 121, and the first groove 111 mate with the first protrusion 123. The third chip 130 is disposed on the second side 122, and the second groove 131 is cooperatively connected with the second protrusion 124. The first chip 110 and the third chip 130 are symmetrically arranged about a central axis of the second chip 120 thus forming the light-emitting chip 100. The first side 121 and the second side 122 are arranged oppositely, so that the first chip 110 and the third chip 130 are respectively arranged on both sides of the second chip 120. It should be noted that the first groove 111 only mate with the first protrusion 123, and the second groove 131 only mate with the second protrusion 124 to prevent the first chip 110 and the third chip 130 of the light emitting chip 100 from being installed in opposite positions. In this embodiment, the first chip 110 is a red chip, the second chip 120 is a green chip, and the third chip 130 is a blue chip. The first chip 110, the second chip 120, and the third chip 130 together form the light-emitting chip 100. Of course, the first chip 110 is not to be limited to the red chip, the second chip 120 is not to be limited to the green chip, and the third chip 130 is not to be limited to the blue chip. Designers may choose a design depending on the actual situation, and there are no restrictions thereto.

In the light-emitting chip 100 of this embodiment, a first protrusion 123 and a second protrusion 124 are disposed on the second chip 120, a first groove 111 is defined in in the first chip 110, and a second groove 131 is disposed on the third chip 130, so that the first chip 110 and the third chip 130 may be respectively installed on the first side 121 and the second side 122 of the second chip 120 that are opposite to each other, so that the first chip 110, the second chip 120, and the third chip 130 are assembled together to form the light-emitting chip 100. Furthermore, the first protrusion 123 only mate with the first groove 111, and the second protrusion 124 only mate with the second groove 131. There will be no assembly errors of the light-emitting chip 100; there will only be situations where the assembly of the light-emitting chip 100 is completed or not. When the light-emitting chip 100 is installed in a Micro-LED display screen, compared with the RGB solution that requires three chips of red, green and blue to be evenly spaced together on a horizontal plane to form an RGB effect, the light-emitting chip 100 of this embodiment has a relatively low requirement for the mass transfer processes when installed in a Micro-LED display. Since the first chip 110, the third chip 130, and the second chip 120 are first assembled together to form the light-emitting chip 100 which is then installed in the light board 200, the number of chips that require mass transfer and installation is sharply reduced for the light board 200 using the light-emitting chip 100 of this embodiment, and the requirements on the mass transfer process is reduced, thereby improving the production yield of Micro-LED displays, and also reducing the difficulty of assembly, making it easier to produce Micro-LED displays.

A light-emitting surface area of the first chip 110 is S1. A light-emitting surface area of the second chip 120 is S2. A light-emitting surface area of the third chip 130 is S3. The S1, the S2 and the S3 are all equal to ensure that after each of the light-emitting chips 100 is installed on the light board 200, the first chip 110, the second chip 120, and the third chip 130 of the light-emitting chip 100 emit light in equal areas, so as to ensure that there will be no abnormalities when the screen is displaying an image. It should be noted that the light-emitting surfaces of the first chip 110, the second chip 120, and the third chip 130 refer to the surfaces of the first chip 110, the second chip 120, and the third chip 130 facing away from the bottom plate 300. The light-emitting chip 100 formed by combining the first chip 110, the third chip 130, and the second chip 120 may have a rectangular structure. Of course, the light-emitting chip 100 formed by combining the first chip 110, the second chip 120, and the third chip 130 may also be in other shapes and structures, such as a cylinder, a cube, etc. Designers can choose a design depending on the actual situation, and there are no restrictions thereto.

As illustrated in FIGS. 1 to 3, the first chip 110 includes a first connecting piece 113, and the third chip 130 includes a second connecting piece 133. When the first chip 110 and the third chip 130 are combined with the second chip 120 to form the light-emitting chip 100, the first chip 110 and the second chip 120 are electrically connected through the first connecting piece 113, and the third chip 130 and the second chip 120 are connected through the second connecting piece 133. The first connecting piece 113 and the second connecting piece 133 may be conductor layers or connecting circuit layers. In this way, with the assembled light-emitting chip 100, it is only needed to set pins on the first chip 110 or the third chip 130 or the second chip 120 alone, so that the first chip 110, the third chip 130, and the second chip 120 of the light-emitting chip 100 can be powered up together through these pins, thereby achieving a design of saving pins. In this embodiment, if the first connecting piece 113 and the second connecting piece 133 are conductor layers, the conductor layers may be made of metallic copper, so that the conductor layer has good electrical conductivity.

Of course, the designers may also sequentially set pins on the first chip 110, the third chip 130, and the second chip 120 for connection and power supply. At the same time, the first chip 110 and the second chip 120 may also be powered together through the first connecting piece 113, and the third chip 130 and the second chip 120 may also be powered together through the second connecting piece 133, thereby improving the fault tolerance rate for abnormal pins on the first chip 110, the third chip 130, and the second chip 120 when assembling the light-emitting chip 100 onto the light board 200. For each light-emitting chip 100, it is only needed to ensure that the pin(s) of any one of the first chip 110, the third chip 130, or the second chip 120 is normal before power can be used, which greatly improves the fault tolerance rate of installation. It should be noted that the first connecting piece 113 only needs to electrically connect the first chip 110 and the second chip 120, and the second connecting piece 133 only needs to electrically connect the third chip 130 and the second chip 120. Designers can choose and design the specific connection structures according to actual needs, and there are no restrictions thereto.

Further, in order to more conveniently assemble the first chip 110 and the third chip 130 onto the first side 121 and the second side 122 of the second chip 120 respectively, a first magnetic attraction layer 125 is disposed on the first protrusion 123, a second magnetic attraction layer 112 is disposed in the first groove 111, a third magnetic attraction layer 126 is disposed on the second protrusion 124, and a fourth magnetic attraction layer 132 is disposed in the second groove 131. The first magnetic attraction layer 125 and the second magnetic attraction layer 112 are attracted to each other. The third magnetic attraction layer 126 and the fourth magnetic attraction layer 132 are attracted to each other. The first magnetic attraction layer 125 and the third magnetic attraction layer 126 have opposite polarities. The second magnetic attraction layer 112 and the fourth magnetic attraction layer 132 have opposite polarities. When assembling the light-emitting chip 100, since the first groove 111 is fitted with the first protrusion 123, and the second groove 131 is fitted with the second protrusion 124, the second magnetic attraction layer 112 in the first groove 111 of the first chip 110 is attracted to the first magnetic attraction layer 125 of the first protrusion 123 of the second chip 120 so that the first chip 110 and the second chip 120 moving towards each other so that the first groove 111 of the first chip 110 can be more easily fitted with the first protrusion 123 of the second chip 120. The fourth magnetic attraction layer 132 in the second groove 131 of the third chip 130 is attracted to the third magnetic attraction layer 126 of the second protrusion 124 of the second chip 120 so that the third chip 130 and the second chip 120 approach each other, causing the third chip 130 and the second chip 120 to approach each other, so that the second groove 131 of the third chip 130 can be more easily fitted with the second protrusion 124 of the second chip 120. Under the action of the first magnetic attraction layer 125, the second magnetic attraction layer 112, the third magnetic attraction layer 126, and the fourth magnetic attraction layer 132, the first chip 110, the third chip 130 and the second chip 120 are more easily assembled to form the light-emitting chip 100. It should be noted that although the second magnetic attraction layer 112 of the first chip 110 will attract the fourth magnetic attraction layer 132 of the third chip 130, since the second magnetic attraction layer 112 of the first chip 110 is located in the first groove 111 and the fourth magnetic attraction layer 132 of the third chip 130 is located in the second groove 131, even if the first chip 110 and the third chip 130 are attracted to each other, the first chip 110 and the third chip 130 can be separated by a slight force.

As illustrated in FIG. 4, as a second embodiment of this application, an assembling apparatus 900 is disclosed. The assembling apparatus 900 is used for assembling the light-emitting chip 100. The assembling apparatus 900 includes a first turntable 910, a second turntable 920, a third turntable 930, a first driving assembly 940, and a second driving assembly 950. The first turntable 910 is connected to the first driving assembly 940 so that the first driving assembly 940 drives the first turntable 910 to rotate. The second driving assembly 950 is connected to the third turntable 930 so that the second driving assembly 950 drives the third turntable 930 to rotate. The second turntable 920 is disposed between the first turntable 910 and the third turntable 930. One end of the second turntable 920 abuts on the first turntable 910, and the other end abuts on the third turntable 930. The first turntable 910 includes a first screening hole 911, the second turntable 920 includes a second screening hole 921, and the third turntable 930 includes a third screening hole 931. The first screening hole 911, the second screening hole 921, and the third screening hole 931 can be rotated to correspond. The first turntable 910 includes a first snap piece 912, and the second turntable 920 includes a first catching groove 922. When the first snap piece 912 is fitted with the first catching groove 922, the first screening hole 911 corresponds to the second screening hole 921.

When using the assembling apparatus 900 to assemble the light-emitting chip 100, firstly, the first screening hole 911, the second screening hole 921, and the third screening hole 931 are misaligned. Then the first chips 110, the second chips 120, and the third chips 130 are poured into the first turntable 910. The first drive assembly 940 drives the first turntable 910 to reciprocate, so that the first chips 110, the second chips 120, and the third chips 130 located in the first turntable 910 make irregular movements, so that the first chips 110, the second chips 120 and the third chips 130 can be assembled into the light-emitting chips 100 during the moving process. When the number of assembled light-emitting chips 100 in the first turntable 910 is sufficient, the first driving assembly 940 stops operating, and the first turntable 910 is rotated so that the first snap piece 912 is fitted with the first catching groove 922, so that the first screening hole 911 and the second screening hole 921 face each other. The third turntable 930 is then driven to rotate through the second driving assembly 950. When the third turntable 930 rotates until the third screening hole 931 corresponds to the first screening hole 911 and the second screening hole 921, the unassembled first chips 110, third chips 130, and second chips 120 will be separated from the assembling apparatus 900 through the first screening hole 911, the second screening hole 921, and the third screening hole 931 that face each other, while the assembled light-emitting chips 100 will remain in the first turntable 910 for the next manufacturing procedure. The size of each the first screening hole 911, the second screening hole 921, and the third screening hole 931 is smaller than the light emitting chip 100 and larger than the first chip 110, the second chip 120, and the third chip 130 so as to ensure that the unassembled first chips 110, third chips 130, and second chips 120 can be separated from the assembling apparatus 900. The first driving assembly 940 includes a first motor and a first power connection shaft. The output shaft of the first motor is connected to the first power connection shaft. The first power connection shaft is fixedly connected to the first turntable 910 to drive the first turntable 910 to rotate. The second driving assembly 950 includes a second motor and a second power connection shaft. The output shaft of the second motor is connected to the second power connection shaft. The second power connection shaft is fixedly connected to the third turntable 930 to drive the third turntable 930 to rotate.

As illustrated in FIG. 5, as a third embodiment of this application, a method of assembling a light-emitting chip is disclosed, which is applied to the light-emitting chips 100 described in the foregoing embodiments. The method includes the following operations:
placing the first chips, the second chips and the third chips into an assembling apparatus;
starting the assembling apparatus to move the first chips, the second chips, and the third chips to be combined and assembled together to form the light-emitting chip;
wherein the first groove only mate with the first protrusion, and the second groove only mate with the second protrusion;
wherein the assembling apparatus is the assembling apparatus described in the foregoing embodiments.

In the method of assembling the light-emitting chip of this embodiment, by using the assembling apparatus 900 and the first chips 110, the second chips 120, and the third chips 130, the assembling apparatus 900 can realize automatic assembly of the light-emitting chips 100, and can automatically screen out the assembled light-emitting chips 100. Thus, the light-emitting chips 100 can be formed before being installed on the light board 200. Compared with the RGB solution that requires three chips of red, green and blue to be evenly spaced in a horizontal plane to form an RGB effect, the light-emitting chip 100 of this embodiment has relatively a low requirement for the mass transfer process when installed on a Micro-LED display screen. Since the first chip 110, the third chip 130, and the second chip 120 are first assembled into the light-emitting chip 100 and then installed on the light board 200, the number of chips that require mass transfer and installation in the light board 200 using the light-emitting chip 100 of this embodiment is drastically reduced, and the requirements for the mass transfer process are reduced, thereby improving the production yield of the Micro-LED display and also reducing the difficulty of assembly, making it easier to produce Micro-LED displays.

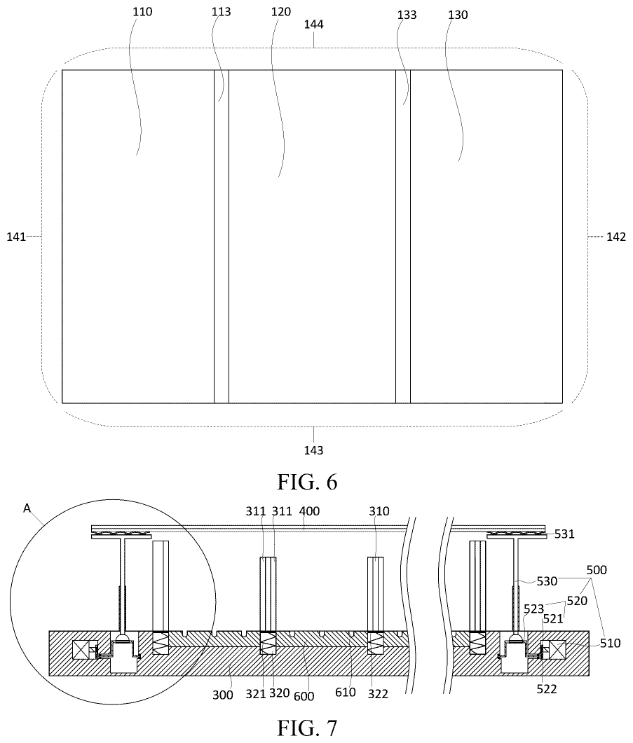

As illustrated in FIGS. 1 and 6, as a fourth embodiment of this application, which is an improvement of the first embodiment of this application, a light-emitting chip 100 is disclosed. The light-emitting surface of the light-emitting chip 100 includes a first electrostatic coating 140. The light-emitting surface of the light-emitting chip 100 is a top surface of the light-emitting chip 100. A second electrostatic coating 141 is disposed on the side of the light-emitting chip 100 on which the first chip 110 is disposed. A third electrostatic coating 142 is disposed on the side of the light-emitting chip 100 where the third chip 130 is disposed. A front side of the light-emitting chip 100 includes a fourth electrostatic coating 143. A back side of the light-emitting chip 100 includes a fifth electrostatic coating 144. The front and back sides of the light-emitting chip 100 are each adjacent to the light-emitting surface, and the front and back sides of the light-emitting chip 100 are arranged opposite to each other. The second electrostatic coating 141 and the third electrostatic coating 142 have opposite charge polarities. The fourth electrostatic coating 143 and the fifth electrostatic coating 144 have opposite charge polarities. The first electrostatic coating 140 is a positively charged electrostatic coating. In this embodiment, the first electrostatic coating 140, the second electrostatic coating 141, the third electrostatic coating 142, the fourth electrostatic coating 143, and the fifth electrostatic coating 144 are disposed on the light-emitting chip 100, and the second electrostatic coating 141 and the third electrostatic coating 142 have opposite charge polarities, and the fourth electrostatic coating 143 and the fifth electrostatic coating 144 have opposite charge polarities, so that after the light-emitting chip 100 is assembled on the light board 200, orientational positioning can be performed through the first electrostatic coating 140, the second electrostatic coating 141, the third electrostatic coating 142, the fourth electrostatic coating 143, and the fifth electrostatic coating 144 to complete the assembly of the light-emitting chip 100, ensuring that the arrangement of each light-emitting chip 100 is equal. It should be noted that designers can set corresponding capacitor plates to realize the direction positioning of the first electrostatic coating 140, the second electrostatic coating 141, the third electrostatic coating 142, the fourth electrostatic coating 143, and the fifth electrostatic coating 144. Specific usage conditions are described in conjunction with the following examples.

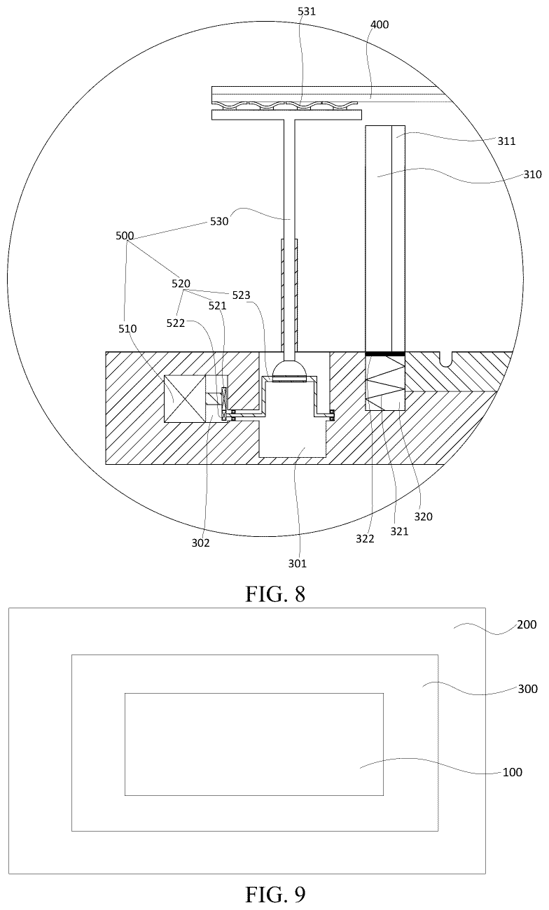

As illustrated in FIGS. 7 and 8, as a fifth embodiment of this application, a light board 200 is disclosed. The light board 200 includes a bottom plate 300, a plurality of light-emitting chips 100, a main capacitor plate 400, and an assembling structure 500. The bottom plate 300 includes a plurality of partition plates 310. The plurality of partition plates 310 divide the bottom plate 300 into a plurality of sections. The plurality of light-emitting chips 100 are respectively arranged in a plurality of the sections. A first electrostatic coating 140 is disposed on a top surface of the light-emitting chip 100. The main capacitor plate 400 is arranged opposite to the bottom plate 300. The light-emitting chips 100 are disposed between the bottom plate 300 and the main capacitor plate 400. The assembling structure 500 is arranged on the bottom plate 300. The assembling structure 500 is connected to the main capacitor plate 400. The assembling structure 500 drives the main capacitor plate 400 to reciprocate toward or away from the bottom plate 300. The light-emitting chips 100 are the light-emitting chips 100 described in the above embodiment. The partition plate 310 further includes a sub-capacitor plate 311. The sub-capacitor plate 311 is disposed on the side of the partition plate 310 facing the section. The polarities of the opposite sub-capacitor plates 311 in each of the sections are opposite. The adjacent sub-capacitor plates 311 have the same polarity. Taking one section as an example. The section includes four directions: front, back, left, and right. The sub-capacitor plate 311 located in the front position and the sub-capacitor plate 311 located in the rear position have opposite polarities. The sub-capacitor plate 311 located on the left position and the sub-capacitor plate 311 located on the right position have opposite polarities. The sub-capacitor plate 311 located in the front position may have the same polarity as the sub-capacitor plate 311 located in the left position, and the sub-capacitor plate 311 located in the rear position may have the same polarity as the sub-capacitor plate 311 located in the right position. During assembly, the light-emitting chips 100 can be laid directly into the sections. There is no need to first adjust the orientations in which the light-emitting chips 100 are placed, just ensuring that the light-emitting chips 100 are laid in each section would suffice. The main capacitor plate 400 is then installed on the assembling structure 500 so that the main capacitor plate 400 is connected to the assembling structure 500. When the main capacitor plate 400 is energized, the light-emitting chips 100 will gradually move from the sections toward the main capacitor plate 400 under the action of the first electrostatic coating 140. Then the assembling structure 500 is used to drive the main capacitor plate 400 to move in a direction away from the bottom plate 300, thereby driving the light-emitting chips 100 to leave the sections. At this time, the light-emitting chips 100 have enough turning space, and the light-emitting chips 100 can rotate to make the top surface of the light-emitting chip 100 contacting the main capacitor plate 400. At this time, all the light-emitting chips 100 on the light board 200 are adjusted so that the top surfaces of the light-emitting chips 100 abut on the main capacitor plate 400. The assembling structure 500 is then used to drive the main capacitor plate 400 to move in the direction of the bottom plate 300 to install the light-emitting chips 100 into the sections. Then, the sub-capacitor plates 311 arranged in various orientations in the sections are energized. Under the action of the sub-capacitor plates 311 and the second electrostatic coating 141, the third electrostatic coating 142, the fourth electrostatic coating 143, and the fifth electrostatic coating 144 disposed on the light-emitting chips 100, the light-emitting chips 100 are completely oriented so that the directions of all light-emitting chips 100 on the light board 200 are consistent with each other, thereby completing the massive transfer and installation of the light-emitting chips 100 on the light board 200. In summary, in the light board 200 in this embodiment, the first electrostatic coating 140, the second electrostatic coating 141, the third electrostatic coating 142, the fourth electrostatic coating 143, and the fifth electrostatic coating 144 are disposed on the light emitting chip 100, and sub-capacitor plates 311 are arranged in various orientations in the sections. The direction positioning of each light-emitting chip 100 is therefore performed by the first electrostatic coating 140, the second electrostatic coating 141, the third electrostatic coating 142, the fourth electrostatic coating 143, and the fifth electrostatic coating 144, thus completing the assembly of the light-emitting chips 100 and ensuring that the arrangement of each light-emitting chip 100 is equal, thereby improving the mass transfer efficiency and accuracy of the light-emitting chips 100. Compared with the original Micro-LED mass transfer process, the requirements for the Micro-LED mass transfer process are reduced, the production yield of Micro-LED displays is improved, and the difficulty of assembly is reduced, making it easier to produce Micro-LED displays. The designs of the light board 200 and the light-emitting chips 100 in this embodiment complement each other.

The assembling structure 500 includes a driving piece 510, a transmission assembly 520, and a connecting rod 530. The driving piece 510 is connected to the transmission assembly 520. The transmission assembly 520 is connected to the connecting rod 530. The connecting rod 530 is connected to the main capacitor plate 400. When the driving piece 510 is operating, the driving piece 510 drives the transmission assembly 520 to move. The transmission assembly 520 drives the connecting rod 530 to move back and forth in the direction from the bottom plate 300 to the main capacitor plate 400, thereby driving the main capacitor plate 400 to move. The connecting rod 530 includes a suction piece 531. The suction piece 531 is connected to the main capacitor plate 400 to adsorb the main capacitor plate 400 on the connecting rod 530. In this embodiment, the suction piece 531 may be a small suction ball, and the driving piece 510 may be a motor. The motor is connected to the connecting rod 530 through a transmission assembly 520 to drive the main capacitor plate 400 to move. The main capacitor plate 400 is adsorbed on the connecting rod 530 through the small suction balls. The small suction ball may be provided in multiple. The multiple small suction balls are adsorbed on the main capacitor plate 400 at the same time to ensure the stability of the connection between the connecting rod 530 and the main capacitor plate 400. The assembling structure 500 may be provided in multiple. The multiple assembling structures 500 are respectively disposed on the four sides of the bottom plate 300 to achieve stable support for the main capacitor plate 400. The transmission assembly 520 includes a first transmission gear 521, a second transmission gear 522, and a crank rod 523. The driving piece 510 is a motor. An output shaft of the motor is connected to the first transmission gear 521. The first transmission gear 521 meshes with the second transmission gear 522. The second transmission gear 522 is connected to the crank rod 523. The crank rod 523 is connected to the connecting rod 530. In this way, when the assembling structure 500 of this embodiment is in use, the motor is started to work, the output shaft of the motor is connected to the first transmission gear 521, the first transmission gear 521 meshes with the second transmission gear 522, the second transmission gear 522 is connected to the crank rod 523, and the crank rod 523 is connected to the connecting rod 530. Thus, the motor can directly drive the crank rod 523 through the first transmission gear 521 and the second transmission gear 522, so that the crank rod 523 makes a circular motion. The connecting rod 530 disposed on the crank rod 523 will move with the movement of the crank rod 523, thereby driving the main capacitor plate 400 to move toward or away from the bottom plate 300 thus making a reciprocating motion. In this embodiment, the first transmission gear 521, the second transmission gear 522, and the crank rod 523 are arranged to drive the movement of the connecting rod 530, and the operation is realized through multi-stage motion transmission. The bottom plate 300 includes an accommodating groove 301 and a receiving groove 302. The accommodating groove 301 and the receiving groove 302 are connected to each other. The motor is arranged in the receiving groove 302. The first transmission gear 521 and the second transmission gear 522 are also arranged in the receiving groove 302. The crank rod 523 is arranged in the accommodating groove 301. One end of the crank rod 523 extends into the receiving groove 302 and is connected with the second transmission gear 522. The crank rod 523 is rotatably arranged in the accommodating groove 301. With this arrangement, most of the assembling structure 500 is disposed inside the bottom plate 300, thereby saving the external space of the bottom plate 300 and making the appearance of the light board 200 more concise and beautiful.

A power supply board 600 is further disposed on the bottom plate 300. The power supply plate 600 includes a connecting hole 610. Pins are disposed on the bottom surface of the light-emitting chip 100. When the light-emitting chip 100 is installed into the section, the pins are located in the connecting holes 610. The power supply board 600 is electrically connected to the light-emitting chip 100 through the connecting holes 610 and pins to provide power for the light-emitting chip 100 for use, thereby display an image.

The bottom plate 300 further includes a sunken groove 320. The sunken groove 320 is arranged corresponding to the partition plate 310. The elastic piece 321 is disposed in the sunken groove 320. A support plate 322 is disposed on one end of the partition plate 310 adjacent to the sunken groove 320. One end of the elastic piece 321 abuts on the bottom of the sunken groove 320, and the other end abuts on the support plate 322. When the main capacitor plate 400 moves toward the bottom plate 300, the main capacitor plate 400 contacts the partition plate 310 to drive the partition plate 310 to move toward the bottom of the sunken groove 320. After the orientation adjustment of the light-emitting chips 100 is completed, the assembling structure 500 drives the main capacitor plate 400 to move toward the bottom plate 300. The main capacitor plate 400 abuts on the partition plate 310 to drive the partition plate 310 to move toward the bottom of the sunken groove 320, thereby pressing the light-emitting chip 100 in the section to avoid problems such as movement of the light-emitting chip 100 due to the orientation in which the light board 200 is placed during use. At the same time, the light-emitting chip 100 can also be tightly pressed on the bottom plate 300 to prevent the pins of the light-emitting chip 100 from being separated from the connecting holes 610 of the power supply board 600 and causing the light-emitting chip 100 to be powered off.

As illustrated in FIG. 9, as a sixth embodiment of this application, a light board 200 is disclosed. The light board 200 includes a bottom plate 300 and the light-emitting chip 100 as described in the above embodiment. The light-emitting chip 100 is installed on the bottom plate 300. In the light board 200 of this embodiment, the first protrusion 123 and the second protrusion 124 are disposed on the second chip 120, the first groove 111 is defined in the first chip 110, and a second groove 131 is defined in the third chip 130, so that the first chip 110 and the third chip 130 can be respectively installed on the first side 121 and the second side 122 of the second chip 120 that are opposite to each other, so that the first chip 110, the second chip 120, and the third chip 130 are assembled together to form the light emitting chip 100. When the light-emitting chip 100 is used and installed on a Micro-LED display screen, compared with the RGB solution that requires three chips of red, green and blue which are evenly spaced together on a horizontal plane to form an RGB effect, the light-emitting chips 100 of this embodiment have relatively low requirements for mass transfer processes when installed on a Micro-LED display. Since the first chip 110, the third chip 130 and the second chip 120 are first assembled together as the light-emitting chip 100 which is then installed on the light board 200, the number of chips that require mass transfer and installation in the light board 200 using the light-emitting chip 100 of this embodiment is drastically reduced, and the requirements for the mass transfer process are reduced, thereby improving the production yield of Micro-LED displays and also reducing the difficulty of assembly, making it easier to produce Micro-LED displays.

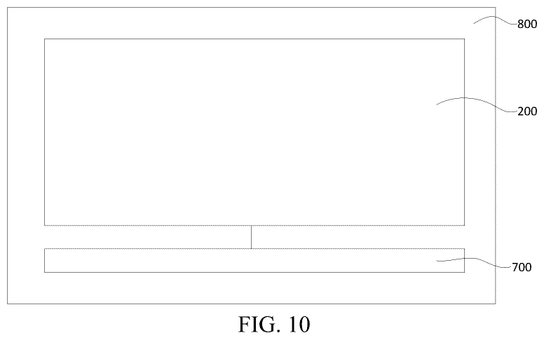

As illustrated in FIG. 10, as a seventh embodiment of this application, a display device 800 is disclosed. The display device 800 includes a driving circuit 700 and the light board 200 as described in the above embodiment. The driving circuit 700 is used to drive the light board 200. When the light-emitting chips 100 of the display device 800 of this embodiment are installed on the Micro-LED display screen, the requirements for the mass transfer process are relatively low. Since the first chip 110, the third chip 130 and the second chip 120 are first assembled as the light-emitting chip 100 which is then installed on the light board 200, the number of chips that require mass transfer and installation in the light board 200 is drastically reduced, and the requirements for the mass transfer process are reduced, thereby improving the production yield of the display device 800, and also reducing the difficulty of assembly, making it easier to produce Micro-LED displays.

It should be noted that the limitations of various operations involved in this solution will not be deemed to limit the order of the operations, provided that they do not affect the implementation of the specific solution, so that the operations written earlier may be executed earlier or they may also be executed later or even at the same time. As long as the solution can be implemented, they should all be regarded as falling in the scope of protection of this application.

It should be noted that the inventive concept of this application can be formed into many embodiments, but the length of the application document is limited and so these embodiments cannot be enumerated one by one. The technical features can be arbitrarily combined to form a new embodiment, and the original technical effect may be enhanced after the various embodiments or technical features are combined.

The foregoing description is merely a further detailed description of this application made with reference to some specific illustrative embodiments, and the specific implementations of this application will not be construed to be limited to these illustrative embodiments. For those having ordinary skill in the technical field to which this application pertains, numerous simple deductions or substitutions may be made without departing from the concept of this application, which shall all be regarded as falling in the scope of protection of this application.

What is claimed is:

1. A light-emitting chip applied to a light board, the light-emitting chip comprising:
a first chip, comprising a first groove;
a second chip, comprising a first side and a second side, wherein there is disposed a first protrusion on the first side and a second protrusion on the second side; and
a third chip, comprising a second groove;
wherein the first chip is disposed on the first side of the second chip, and the first groove is mated with the first protrusion; wherein the third chip is disposed on the second side of the second chip, and the second groove is mated with the second protrusion; wherein the first chip and the third chip are symmetrically arranged about a central axis of the second chip so that the first chip and the third chip are combined with the second chip to form the light-emitting chip.

2. The light-emitting chip as recited in claim 1, wherein there is disposed a first magnetic attraction layer on the first protrusion, a second magnetic attraction layer in the first groove, a third magnetic attraction layer on the second protrusion, and a fourth magnetic attraction layer in the second groove; wherein the first magnetic attraction layer and the second magnetic attraction layer are operative to be attracted to each other, and wherein the third magnetic attraction layer and the fourth magnetic attraction layer are operative to be attracted to each other;
wherein the first magnetic attraction layer and the third magnetic attraction layer have opposite polarities, and wherein the second magnetic attraction layer and the fourth magnetic attraction layer have opposite polarities.

3. The light-emitting chip as recited in claim 2, wherein the first chip has a light-emitting surface area of S1, the second chip has a light-emitting surface area of S2, and third chip has a light-emitting surface area of S3; wherein S1, S2, and S3 are all equal to each other.

4. The light-emitting chip as recited in claim 1, wherein there is disposed a first electrostatic coating on a light-emitting surface of the light-emitting chip, a second electrostatic coating on a side of the light-emitting chip on which the first chip is disposed, and a third electrostatic coating on a side of the light-emitting chip on which the third chip is disposed; wherein there is disposed a fourth electrostatic coating on a front side of the light-emitting chip, and there is disposed a fifth electrostatic coating on a back side of the light-emitting chip;
wherein the second electrostatic coating and the third electrostatic coating have opposite charge polarities, and wherein the fourth electrostatic coating and the fifth electrostatic coating have opposite charge polarities.

5. The light-emitting chip as recited in claim 1, wherein the first chip comprises a first connecting piece, and the third chip comprises a second connecting piece; wherein when the first chip and the third chip are combined with the second chip to form the light-emitting chip, the first chip and the second chip are electrically connected to each other through the first connecting piece, and wherein the third chip and the second chip are electrically connected to each other through the second connecting piece;
wherein the first connecting piece and the second connecting piece are each a conductor layer.

6. The light-emitting chip as recited in claim 4, wherein the first electrostatic coating is a positively charged electrostatic coating.

7. The light-emitting chip as recited in claim 5, wherein the conductor layer is made of metallic copper.

8. The light-emitting chip as recited in claim 1, wherein the light-emitting chip has a rectangular structure.

9. The light-emitting chip as recited in claim 1, wherein the first side and the second side are disposed opposite to each other so that the first chip and the third chip are respectively disposed on both sides of the second chip.

10. The light-emitting chip as recited in claim 1, wherein the first chip is a red chip, the second chip is a green chip, and the third chip is a blue chip; wherein the first chip, the second chip, and the third chip collectively form the light-emitting chip.

11. The light-emitting chip as recited in claim 1, wherein the first chip comprises a first connecting piece, and the third chip comprises a second connecting piece; wherein when the first chip and the third chip are combined with the second chip to form the light-emitting chip, the first chip and the second chip are electrically connected to each other through the first connecting piece, and wherein the third chip and the second chip are electrically connected to each other through the second connecting piece;
wherein the first connecting piece and the second connecting piece are each a connecting circuit layer.

12. A light board applied to a display device, the light board comprising a bottom plate and a light-emitting chip; wherein the light-emitting chip comprises:
a first chip, comprising a first groove;
a second chip, comprising a first side and a second side, wherein there is disposed a first protrusion on the first side and a second protrusion on the second side; and
a third chip, comprising a second groove;
wherein the first chip is disposed on the first side of the second chip, and the first groove is mated with the first protrusion, wherein the third chip is disposed on the second side of the second chip, and the second groove is mated with the second protrusion;
wherein the first chip and the third chip are symmetrically arranged about a central axis of the second chip so that the first chip and the third chip are combined with the second chip to form the light-emitting chip, wherein the light-emitting chip is installed on the bottom plate.

13. The light board as recited in claim 12, wherein there is disposed a first magnetic attraction layer on the first protrusion, a second magnetic attraction layer in the first groove, a third magnetic attraction layer on the second protrusion, and a fourth magnetic attraction layer in the second groove; wherein the first magnetic attraction layer and the second magnetic attraction layer are operative to be attracted to each other, and wherein the third magnetic attraction layer and the fourth magnetic attraction layer are operative to be attracted to each other;
wherein the first magnetic attraction layer and the third magnetic attraction layer have opposite polarities, and wherein the second magnetic attraction layer and the fourth magnetic attraction layer have opposite polarities.

14. The light board as recited in claim 16, wherein the first chip has a light-emitting surface area of S1, the second chip has a light-emitting surface area of S2, and the third chip has a light-emitting surface area of S3; wherein S1, S2, and S3 are all equal to each other.

15. The light board as recited in claim 12, wherein there is disposed a first electrostatic coating on a light-emitting surface of the light-emitting chip, a second electrostatic coating disposed on a side of the light-emitting chip on which the first chip is disposed, and a third electrostatic coating disposed on a side of the light-emitting chip on which the third chip is disposed; wherein there is disposed a fourth electrostatic coating on a front side of the light-emitting chip, and a fifth electrostatic coating disposed on a back side of the light-emitting chip;
wherein the second electrostatic coating and the third electrostatic coating have opposite charge polarities, and wherein the fourth electrostatic coating and the fifth electrostatic coating have opposite charge polarities.

16. The light board as recited in claim 12, wherein the light board further comprises a main capacitor plate and an assembling structure; wherein there is disposed a plurality of partition plates on the bottom plate, the plurality of partition plates dividing the bottom plate into a plurality of sections, and wherein a plurality of the light-emitting chips are respectively arranged in the plurality of sections; wherein there is disposed a first electrostatic coating on a top surface of the light-emitting chip, wherein the main capacitor plate is disposed opposite to the bottom plate, wherein the plurality of light-emitting chips are disposed between the bottom plate and the main capacitor plate; wherein the assembling structure is arranged on the bottom plate, the assembling structure being connected to the main capacitor plate and operative to drive the main capacitor plate to move toward or away from the bottom plate in a reciprocating manner; wherein each of the plurality of partition plates further comprises a sub-capacitor plate disposed on each of both sides of the partition plate facing the respective section; wherein opposite sub-capacitor plates in each section have opposite polarities, and wherein adjacent sub-capacitor plates have the same polarity.

17. The light board as recited in claim 16, wherein the assembling structure comprises a driving piece, a transmission assembly, and a connecting rod; wherein the driving piece is connected to the transmission assembly, wherein the transmission assembly is connected to the connecting rod, and wherein the connecting rod is connected to the main capacitor plate; wherein the driving piece when operating is operative to drive the transmission assembly to move, and the transmission assembly is operative to drive the connecting rod to move back and forth in a direction toward or away from the bottom plate, thereby driving the main capacitor plate to move.

18. The light board as recited in claim 16, wherein the driving piece comprises a motor; wherein the transmission assembly comprises a first transmission gear, a second transmission gear, and a crank rod; wherein the motor comprises an output shaft that is connected to the first transmission gear, wherein the first transmission gear meshes with the second transmission gear, wherein the second transmission gear is connected with the crank rod, and wherein the crank rod is connected with the connecting rod.

19. A method of assembling a light-emitting chip, wherein the light-emitting chip comprises a first chip, a second chip, and a third chip; wherein the second chip comprises a first side and a second side, wherein there is disposed a first protrusion on the first side of the second chip, and a second protrusion disposed on the second side of the second protrusion; wherein the first chip comprises a first groove, and the third chip comprises a second groove; wherein the first chip is disposed on the first side of the second chip, and the first groove is mated with the first protrusion; and wherein the third chip is disposed on the second side of the second chip, and the second groove is mated with the second protrusion; wherein the first chip and the third chip are symmetrically arranged about a central axis of the second chip so that the first chip and the third chip are combined with the second chip to form the light-emitting chip; wherein the method comprises:
placing a plurality of the first chips, a plurality of the second chips and a plurality of the third chips into an assembling apparatus;
starting the assembling apparatus to move the plurality of first chips, the plurality of second chips, and the plurality of third chips about so that they are combined and assembled to form the light-emitting chip;
wherein the first groove is operative to be only mated with the first protrusion, and wherein the second groove is operative to be only mated with the second protrusion.

20. The method as recited in claim 19, wherein there is disposed a first magnetic attraction layer on the first protrusion, a second magnetic attraction layer disposed in the first groove, a third magnetic attraction layer disposed on the second protrusion, and a fourth magnetic attraction layer disposed in the second groove; wherein the first magnetic attraction layer and the second magnetic attraction layer are operative to be attracted to each other, and wherein the third magnetic attraction layer and the fourth magnetic attraction layer are operative to be attracted to each other;
wherein the first magnetic attraction layer and the third magnetic attraction layer have opposite polarities, and wherein the second magnetic attraction layer and the fourth magnetic attraction layer have opposite polarities; wherein the first chip has a light-emitting surface area of S1, the second chip has a light-emitting surface area of S2, and the third chip has a light-emitting surface area of S3; wherein S1, S2, and S3 are all equal to each other.
